(19) United States
(12) Patent Application Publication
(10) Pub. No.: US 2013/0220413 A1
(43) Pub. Date: Aug. 29, 2013

(54) Plasmonic Structures, Methods for Making Plasmonic Structures, and Devices Including Them

(71) Applicants: Michael Kozicki, Phoenix, AZ (US); Minghan Ren, Tempe, AZ (US)

(72) Inventors: Michael Kozicki, Phoenix, AZ (US); Minghan Ren, Tempe, AZ (US)

(73) Assignee: Arizona Board of Regents, a body Corporate of the State of Arizona acting for and on behalf of Arzon, Scottsdale, AZ (US)

(21) Appl. No.: 13/877,700

(22) PCT Filed: Nov. 11, 2011
(86) PCT No.: PCT/US11/60392

§ 371 Date: May 7, 2013

(30) Foreign Application Priority Data
Nov. 14, 2010 (US) 61413453

(51) Int. Cl. H01L 31/0216

(52) U.S. Cl. CPC H01L 31/02168
USPC 136/256; 257/436; 438/72

(57) ABSTRACT

The present invention relates generally to plasmonic structures, methods for making them, and devices including them. In one aspect, a plasmonic structure includes a plurality of metal particles disposed on a substrate; and one or more metal structures electrically coupled to and disposed on a surface of each of the plurality of metal particles. The metal structures have a structure that is different than the structure of the metal particles. The metal structures can be grown, for example, by electrodeposition on the metal particles. Growth of such metal structures can tune the response of the plasmonic structure.

### CROSS-REFERENCE TO RELATED APPLICATIONS

The present application claims the priority of U.S. Provisional Patent Application Ser. No. 61/413,453, filed Nov. 14, 2011, which is hereby incorporated herein by reference in its entirety.

### BACKGROUND OF THE INVENTION

1. Field of the Invention

The present invention relates generally to plasmonic structures, methods for making them, and devices including them.

2. Technical Background

Silver nanoparticles can be created on a surface by surface tension-induced agglomeration. For example, thin layers of silver metal on SiO₂ can be annealed to provide nanoparticles. An example of the results of such a process is shown in FIG. 1, as described in H. A. Atwater and A. Polman, “Plasmonics for improved photovoltaic devices,” Nature Materials, 9, 205-213 (2010), which is hereby incorporated herein by reference in its entirety. For example, the particles of FIG. 1 were made by depositing a 14 nm thick Ag film onto a thermally oxidized silicon wafer (SiO₂ thickness 10 nm) by thermal evaporation and annealed at 200° C. in N₂ ambient for 60 minutes in forming gas.

Such structures can support surface plasmons—excitations of the conduction electrons at the interface between a metal and a dielectric. It is possible to use this effect to concentrate incident light into a semiconductor below the dielectric, thereby increasing the absorption. Such light trapping effects can find use, for example, in solar cells (especially thin film solar cells), and other electro-optic devices. For example, a photovoltaic layer can be thinned by as much as 100× while maintaining efficiency using plasmonic techniques. Plasmonics have also been used to enhance the response of optical sensors and detectors.

The light trapping effects are generally strongest at the peak of the plasmon resonance spectrum. Changing the shape of the nanoparticles can shift the position and the sharpness of the peak. For example, small silver particles on (or embedded in) SiO₂ can be tuned to have plasmon resonances over the entire visible light range and into the infrared. The scattering cross-section for metal nanoparticles can be as high as 10× the geometrical area, such that a 10% coverage could result in the capture of most of the incident light into plasmon excitations. As shown in FIG. 2, also from Atwater and Polman, the shape of the nanoparticle can have a significant effect on the fraction of light scattered into an underlying semiconductor. FIG. 2 shows the fraction of light scattered into the substrate, divided by total scattered power, for different sizes and shapes of Ag particles on Si. Also plotted is the scattered fraction for a parallel electric dipole that is 10 nm from a Si substrate. Particles formed by surface-induced agglomeration can be made roughly hemispherical in nature, and thus can be quite efficient in trapping light.

### SUMMARY OF THE INVENTION

One aspect of the invention is a plasmonic structure including a substrate, a plurality of metal particles disposed on the substrate; and one or more metal structures electrically coupled to and disposed on a surface of each of the plurality of metal particles. The metal structures have a structure that is different than the structure of the metal particles. The metal structures can be formed, for example, by electrodeposition, as described in more detail below. Accordingly, the morphology of the metal structures can be defined by electrodeposition. For example, depending on electrodeposition conditions, the electrodeposited material can plate in a conformal fashion (e.g., dome-shaped), or form as an extended feature such as a whisker or a dendrite. Nucleation can occur from multiple sites from the particle. The deposition of the metal can tend to elongate the overall shape of the metal structure/particle composite as compared to the original particle, as it can occur in the direction of the applied electric field.

Another aspect of the invention is a method for making a plasmonic structure. The method includes providing a substrate having disposed thereon a plurality of metal particles; providing an anode and a cathode and disposing a liquid on the surface of the substrate, such that the liquid is in electrical contact with the anode, the cathode and the plurality of metal particles; and applying a bias voltage across the metal particles and the anode sufficient to grow one or more metal structures electrically coupled to and disposed on each of the plurality of metal particles.

The invention will be further described with reference to embodiments depicted in the appended figures. It will be appreciated that elements in the figures are illustrated for simplicity and clarity and have not necessarily been drawn to scale. For example, the dimensions of some of the elements in the figures may be exaggerated relative to other elements to help to improve understanding of embodiments of the invention.

### BRIEF DESCRIPTION OF THE DRAWINGS

FIG. 1 is a photomicrograph of a plasmonic structure according to the prior art;

FIG. 2 is a graph showing the fraction of light scattered into the substrate (as compared to total scattered power) for different sizes and shapes of Ag particles on Si;

FIG. 3 is a schematic top view and a schematic cross-sectional view of a plasmonic structure according to one embodiment of the invention;

FIG. 4 is a photomicrograph of a dendritic metal structure suitable for use in certain aspects of the invention;

FIG. 5 is a profilometry measurement of another example of a dendritic metal structure suitable for use in certain aspects of the invention;

FIG. 6 is a partial top schematic view of a plasmonic structure according to one embodiment of the invention;

FIG. 7 is a partial top schematic view of a plasmonic structure according to another embodiment of the invention;

FIG. 8 is a schematic top view and a schematic cross-sectional view of a depiction of a method form making a plasmonic structure according to one embodiment of the invention;

FIG. 9 is a schematic top view of dendritic metal structures grown between parallel electrodes;

FIG. 10 is an optical micrograph of a plasmonic structure according to one example of the invention;

FIG. 11 is a set of graphs showing red shift of plasmonic resonance upon growth of metal structures;

FIG. 12 is an optical micrograph of a plasmonic structure according to another example of the invention; and

FIG. 13 is a graph showing red shift of plasmonic resonance upon growth of metal structures.

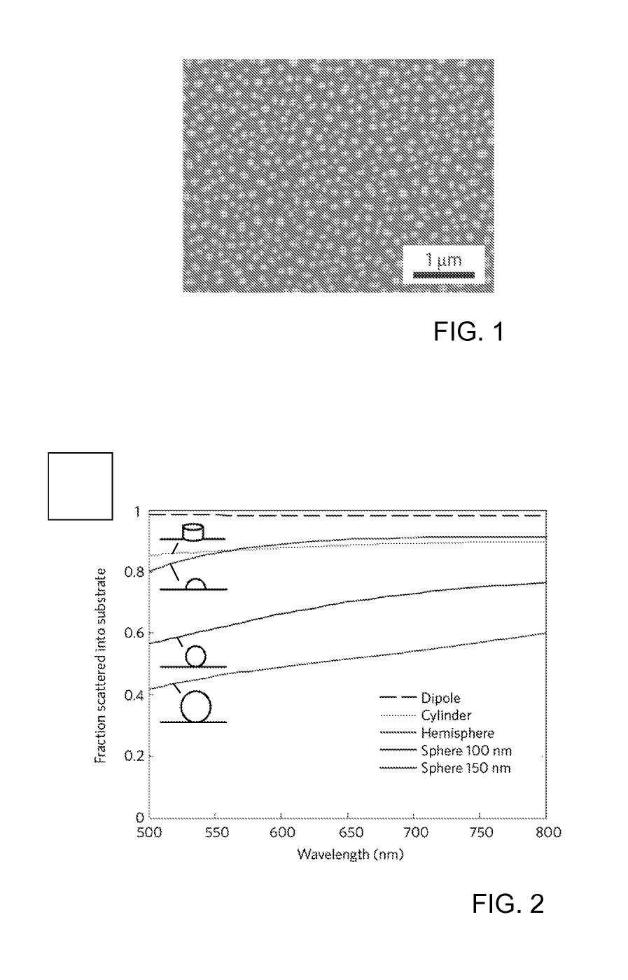

### DETAILED DESCRIPTION OF THE INVENTION

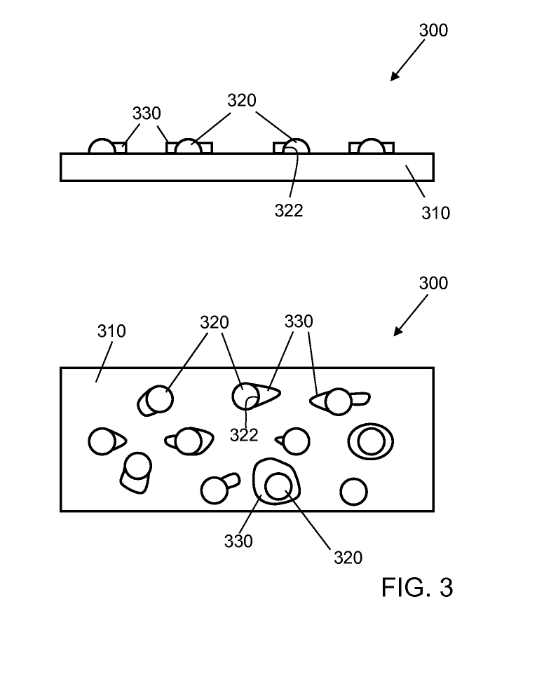

One embodiment of the invention is shown in schematic top view and schematic cross-sectional view in FIG. 3. Plasmonic structure 300 includes a substrate 310, with a plurality of metal particles 320 disposed thereon. Disposed on a surface 322 of the metal particles 320 are metal structures 330, which are electrically coupled to the metal particles. The metal structures need only be in contact with a surface of the metal particles; they need not be on top of the metal particles, but rather can be disposed along a side thereof and extend onto the substrate, as shown in FIG. 3. Moreover, the metal structures can take a variety of shapes and sizes, as shown in FIG. 3. The metal structures can, for example, extend from a surface, or can laterally surround the particle.

Notably, the metal structures have a structure that is different than the structure of the metal particles. That is, the structure differs in some aspect from the structure of the metal particles. For example, in some embodiments, the morphology of the metal structures differs from that of the metal particles. The morphology can, for example, be characteristic for electrodeposition of the metal structures. In other embodiments, the metal of the metal structures differs from that of the metal particles.

The sizes of the particles and their spacing will affect the plasmonic behavior of the plasmonic structure. For example, in certain embodiments, the plurality of metal particles has an average diameter in the range of about 5 nm to about 2 μm. The diameter is measured for the particle only, excluding the metal structure disposed thereon. In one embodiment, the plurality of metal particles has an average diameter in the range of about 50 nm to about 200 nm. In certain embodiments, the plurality of metal particles has an average nearest neighbor distance in the range of about 5 nm to about 2 nm. The average nearest neighbor distance is calculated as the average, over all particles, of the distance from a particle to its nearest neighbor. In one embodiment, the plurality of metal particles has an average nearest neighbor distance in the range of about 50 nm to about 500 nm. The person of skill in the art can determine the appropriate sizes and nearest neighbor distances for the metal particles based on the desired plamsonic effect.

The metal particles can be formed from a wide variety of metals. For example, in certain embodiments, the metal particles are formed from silver, copper, or gold. In another embodiment, the metal particles are formed from aluminum, for example, as described in Y. A. Akimov and W. S. Koh, “Resonant and nonresonant plasmonic nanoparticle enhancement for thin-film silicon solar cells,” Nanotechnology, 21 (2010) 235201-06, which is hereby incorporated herein by reference in its entirety. Of course, other metals can be used, and in some embodiments, the metal particles can be formed from a combination of metals.

As described above with respect to FIG. 2, the metal particles can have a wide variety of shapes. For example, in certain embodiments, and as shown in FIG. 3, the metal particles are substantially hemispherical in shape. Such shapes can be achieved through surface tension induced agglomeration. Of course, agglomeration can be used to achieve other shapes, depending on conditions. Metal particles can be formed from a variety of other methods, including for example, deposition though a mask. For example, hexagonal arrays of triangular particles can be made by deposition through self-assembled arrays of submicron polystyrene spheres, as described in W. A. Murray and W. L Barnes, “Plasmonic Materials,” Adv. Mater., 2007, 29, 3771-3882, which is hereby incorporated herein by reference in its entirety. Deposition through patterned alumina masks has also been used to make arrays of metal particles. Semiconductor fabrication techniques such as photolithography, deposition and etching can also be used to define particle shape and/or arrangement. Different methods can be used to form different shaped particles, as described in Murray and Barnes.

In certain embodiments, the metal particles are at least partially embedded in a dielectric or semiconductor material, such as silicon oxide, silicon nitride, silicon oxynitride or silicon, for example, as described in Atwater and Polman.

The metal structures can be formed from a wide variety of materials and in a wide variety of shapes and configurations, as long as they differ in some way from that of the metal particles (e.g., different shape; different morphology; different metal(s); or a combination thereof).

For example, in certain embodiments, the dendritic metal structure is formed from silver. In other embodiments, the dendritic metal structure is formed from copper. A wide variety of metals can be used in other embodiments, such as iron, zinc, tin or gold. Moreover, metal structures can be formed from mixtures of metals, for example, by electrodeposition from a solution including a mixture of metal ions. The metal structure can, in some embodiments, be formed from a different metal than that of the particles. Of course, in certain embodiments, the metals are the same (i.e., silver metal structures on silver metal particles).

In some embodiments, the metal structures are small in comparison to the particle. For example, in one embodiment, the average ratio of metal structure volume to metal particle volume (averaged over all particles, and including all of any metal structure that interconnects the particle to another) is no greater than 0.5, no greater than 0.2, or even no greater than 0.1.

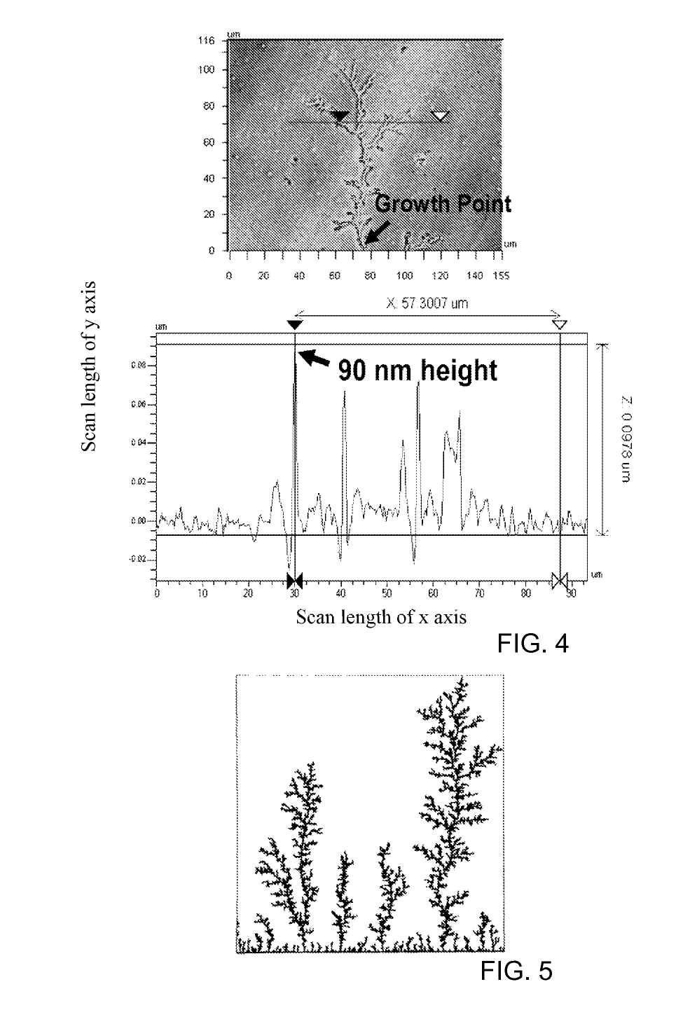

In certain embodiments, the metal structure is a dendritic metal structure. A dendritic metal structure has a multi-branched structure formed of segments of reduced ionic material. In certain embodiments of the invention, the at least one dendritic metal structure has an average individual segment width (i.e., in the plane of the dendritic metal structure) of no more than about 300 μm, no more than about 10 μm, no more than about 1 μm, or even no more than about 200 nm. In certain such embodiments, the at least one dendritic metal structure has an average individual segment width of at least about 20 nm. In one embodiment, the dendritic metal structure has an average thickness (i.e., normal to the plane of the dendritic metal structure) of no more than about 5 μm, no more than about 500 nm, no more than about 200 nm, or even no more than about 50 nm. In certain such embodiments, the at least one dendritic metal structure has an average thickness of at least about 10 nm. FIG. 4 is a photomicrograph of an illustrative example of a dendritic metal structure (as described in International Patent Application Publication no. 2010/077622, which is hereby incorporated herein by reference in its entirety; the dendritic metal structures grown by the present procedures can be substantially similar). In the illustrative example of FIG. 4, dendritic silver structures are grown from a nickel cathode. FIG. 5 is a profilometry measurement of another illustrative example of a dendritic metal structure as described in International Patent Application Publication no. 2010/077622. Electrodeposition from liquids, as described below, can allow the dendritic metal structure to be formed in the absence of a solid electrolyte; accordingly, in some embodiments, substantially no solid electrolyte is in contact with the dendritic metal structure and the metal particles.

In use, the metal structures can be used to broaden the range of plasmon resonances, and therefore broaden the wavelength range over which the metal structure can increase absorption in the device on which it is disposed. The change in resonant frequency and range of resonances is altered by, for example, changes in particle size, distribution of sizes, and particle shape. The metal structures can provide a wider range of overall electronic resonances owing to a wider variety of conduction bands in the metal particle/metal structure composite structures, especially when provided in a non-uniform way. For example, electrodeposition can be used to provide the metal structures in a non-uniform way, as described below.

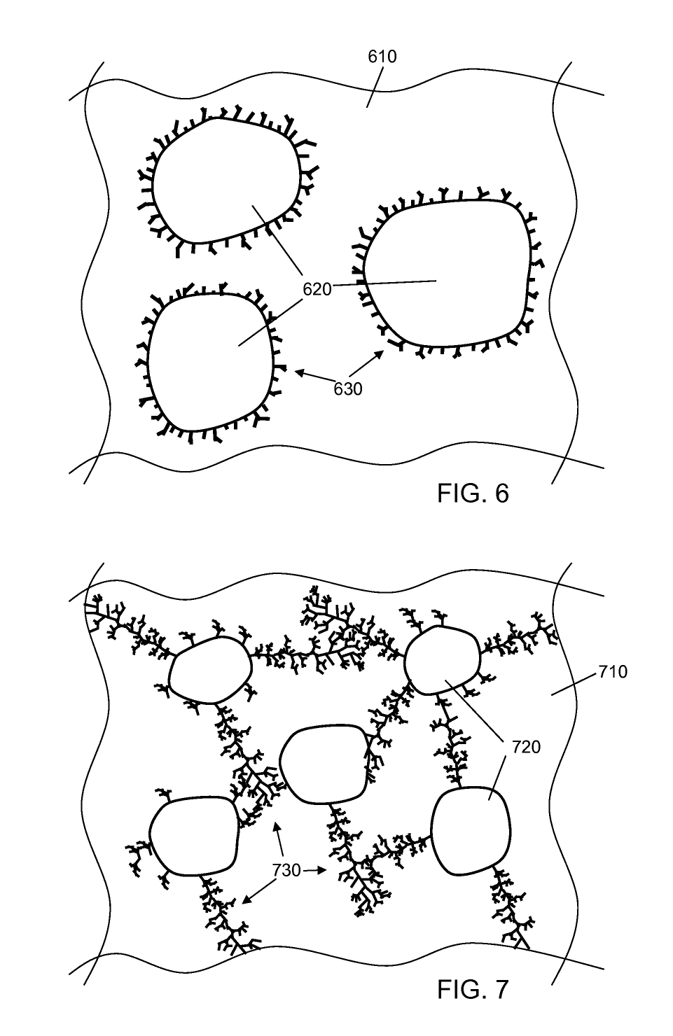

One embodiment of a plasmonic structure is shown in partial top schematic view in FIG. 6. Metal particles 620 are disposed on substrate 610, and have dendritic metal structures 630 extending therefrom. Notably, in this embodiment, the growth of the dendritic metal structures does not interconnect the particles. When electrodeposited, for example, the dendritic metal structures will tend to grow from nucleation sites on the particles; accordingly, due to variation among the particles themselves, and due to the non-uniform growth of the dendrites, the dendritic metal structures will grow in different number and extent on each particle, providing a broadening of spectral response. For example, changing the effective shape of the conduction paths of the electrons in the metal particles by adding the metal structures can be used to both red-shift the plasmonic response and broaden it across more wavelengths.

In certain embodiments of the invention, the metal structures electrically interconnect the metal particles. Murray and Barnes describe theoretical studies of closely-packed aggregates of spherical silver particles, which indicate that plasmon resonances exist over a broad spectral range, in contrast to the fairly narrow range associated with separate metallic nanoparticles. Similarly, metal structures can be used to interconnect isolated nanoparticles to provide a broad spectral range of resonances. Advantageously, as close-packing of particles is not necessary, such metal structures can provide broad spectral response without the high optical absorption that can result from close packing.

One embodiment of a plasmonic structure is shown in partial top schematic view in FIG. 7. Metal particles 720 are disposed on substrate 610, and interconnected by dendritic metal structures 730. Notably, such structures can have low optical occlusion, as the density of particles can be relatively low (e.g., less than 50%, and even less than 20% of the surface area), and the dendritic metal structures are relatively thin (e.g., as described above).

The plasmonic structures described herein can be used in a wide variety of applications. A plasmonic structure can be used to absorb and intensify light at specific wavelengths, depending on the identity of the metal(s) involved and the topography and morphology of the structure. As is familiar to the person of skill in the art, incident light can result in a collective oscillation of electrons at the metal surface. Plasmonic structures have been suggested for use in a wide variety of devices. See, e.g., Atwater and Polman; Murray and Barnes; Akimov et al.; S. Pillai et al., “Surface plasmon enhanced silicon solar cells,” J. App. Phys., 101, 093105 (2007); S. Pillai and M. A. Green, “Plasmonics for photovoltaic applications,” Solar Energy Materials & Solar Cells, 94 (2010) 1481-86; and T. Qiu et al., “Silver fractal networks for surface enhanced Raman scattering substrates,” Appl. Surface Sci., 254 (2008) 5399-5402, each of which is hereby incorporated herein by reference in its entirety.

In one embodiment of the invention, the substrate comprises a photovoltaic cell, e.g., optically coupled to the plasmonic structure. The photovoltaic cell can be any desirable type, such as a single crystal Si photovoltaic cell, an amorphous Si photovoltaic cell, a silicon-on-insulator photovoltaic cell, a III-V semiconductor photovoltaic cell, a II-VI semiconductor photovoltaic cell, a CuInSe₂ photovoltaic cell, or a quantum well photovoltaic cell. The photovoltaic cell can be single or multiple junction, as would be apparent to the person of skill in the art. The plasmonic structures of the present invention can in some embodiments provide high absorption over a broad range of wavelengths.

Notably, the plasmonic structure can be used to concentrate and “fold” the light into a thin semiconductor layer, thereby increasing the absorption. As described in Atwater and Polman, plasmonic structures can offer multiple ways of reducing the physical thickness of the photovoltaic absorber layers while maintaining optical efficiency. For example, the plasmonic structure can be used as subwavelength scattering elements to couple and trap freely propagating plane waves into the phovoltaic layers; and can be used as subwavelength antennae in which the plasmonic near-field is coupled to the photovoltaic layers. Accordingly, in certain embodiments, the light-absorbing photovoltaic layer (i.e., all such layers) of the photovoltaic cell is less than about 50 μm in thickness. In one embodiment, the light-absorbing photovoltaic layer is less than about 10 μm in thickness.

In another embodiment of the invention, the substrate comprises an optical sensor (i.e., one or more layers that change an optical, electrical, mechanical or thermal characteristic in response to absorption of light), e.g., optically coupled to the plasmonic structure. The plasmonic structures described herein can be use to increase light absorption, and therefore increase the response of such devices. The optical sensor can be formed, for example, from a p-n semiconductor junction.

Another aspect of the invention is a method for making a plasmonic structure. The method comprises providing a substrate having disposed thereon a plurality of metal particles; providing an anode and a cathode and disposing a liquid on the surface of the substrate, such that the liquid is in electrical contact with the anode, the cathode and the plurality of metal particles; and applying a bias voltage across the metal particles and the anode sufficient to grow one or more metal structures electrically coupled to and disposed on each of the plurality of metal particles. The metal of the metal structures can be provided by the anode; by metal ions originally provided in the liquid; or a combination thereof.

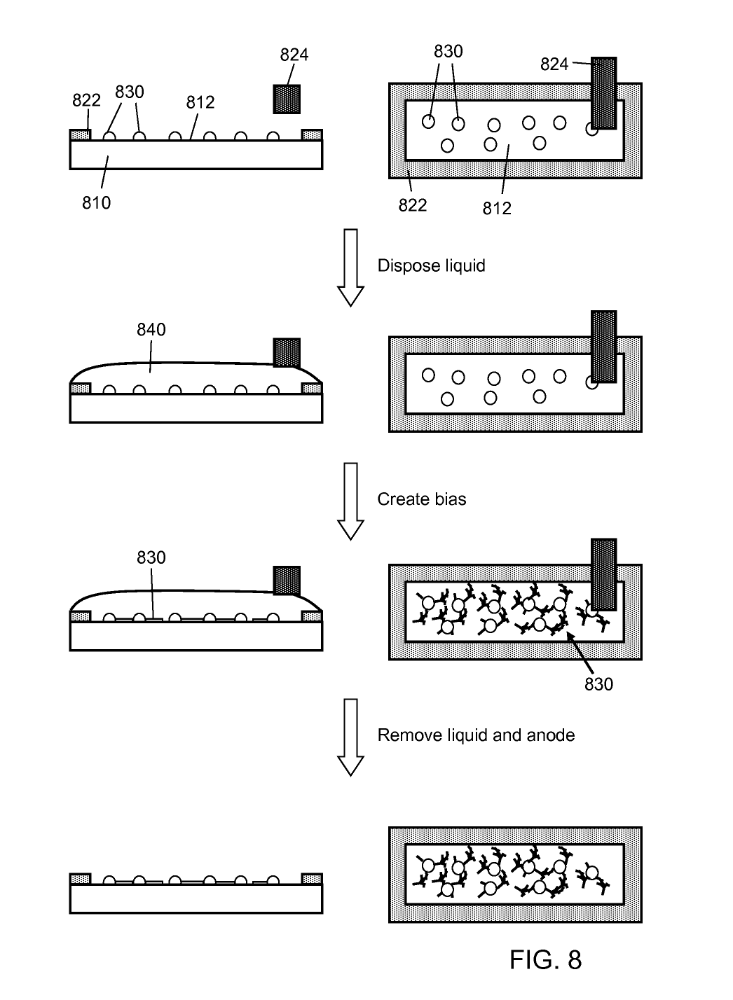

One example of a method is shown in schematic top view and schematic cross-sectional view in FIG. 8. A substrate 810 having a surface 812 and metal particles 820 and a cathode 822 disposed thereon is provided. The metal particles can be provided, for example, by surface tension-induced agglomeration, as described above. Also provided is an anode 824 formed from a metal; in this embodiment, the anode is suspended above the surface 812 of the substrate 810. A liquid 840 in which the metal of the anode is at least partially soluble (i.e., in some cationic form) is then disposed on the surface of the substrate. As shown in schematic side view in FIG. 8, in this embodiment, the liquid is simply disposed as a relatively thin film on the surface of the substrate, held in place by surface tension. In other embodiments, the liquid can be provided in a larger volume, e.g., in a vessel in which the substrate is submerged. The liquid is in electrical contact with both the anode and the cathode. A bias voltage is applied across the cathode and the anode sufficient to grow the metal structures 830 (in this embodiment, dendritic metal structures) extending from the particles. In this example, there may also be some growth from the cathode, which can connect the cathode to the particles to provide an interconnected transparent electrode structure (e.g., as described in International Patent Application Publication no. 2010/077622) that also has plasmonic properties.

An anode and a cathode are positioned relative to the substrate so that the metal structure can be electrodeposited. As a metal structure grows from the metal particle, it is disposed on the surface of the substrate. The anode and/or the cathode can be, for example, also disposed on the surface of the substrate. In other embodiments, the anode, the cathode, or both are not disposed on the dendrite, but rather are just in contact with the liquid. In such embodiments, the anode, the cathode, or both can, for example, be positioned within 1 cm, or even 5 mm of the surface. When the anode and/or the cathode are in contact with the surface, they can help to direct the direction of growth of the dendrites.

In the process of electrodeposition, metal cations in the liquid are reduced at the metal particles. Electrons leak along the surface of the substrate (along with the overlying liquid), combining with metal cations from the liquid on the surface of the metal particle. To replace the metal cations in the liquid and allow for continued growth of the metal structure, the anode can comprise a same metal as the metal of the metal structure. As the metal structure grows by reduction at the metal particle surface, the anode is concomitantly oxidized and dissolved into the liquid, resulting in a net mass transfer from the anode to the growing metal structure. For example, the anode can be formed of silver, a silver alloy, copper or a copper alloy. When the metal is provided by the anode, the liquid need not have any metal ions dissolved in it when it is disposed on the surface of the substrate.

In other embodiments, the anode need not dissolve into the liquid, and the metal structures can be grown only from the metal initially dissolved into the liquid. For example, the anode can be relatively inert, as described below with respect to the cathode. In such embodiments, a relatively large volume of liquid can be provided in order to provide the desired amount of metal cations.

The cathode can be relatively inert and generally does not dissolve during the electrodeposition operation. For example, the cathode can be formed from an inert material such as aluminum, tungsten, nickel, molybdenum, platinum, gold, chromium, palladium, metal silicides, metal nitrides, and doped silicon. Moreover, the bias can be reversed to redissolve metal from the metal structures, thereby providing a method to more precisely tune the extent of growth, and thereby tune the response of the device. Of course, in other embodiments, the cathode need not be formed from an inert material. Indeed, when both electrodes are formed from the metal of the metal structures, either electrode can act as the cathode from which the metal structures grow (i.e., depending on the polarity of the bias), providing additional process flexibility. The person of skill in the art can select appropriate cathode materials based on the necessary electrodeposition conditions. Various configurations of electrodes suitable for use with the present invention are discussed, for example, in U.S. Pat. No. 6,635,914, which is hereby incorporated herein by reference in its entirety.

Contacts may suitably be electrically coupled to the anode and/or cathode to facilitate forming electrical contact to the respective electrode. The contacts may be formed of any conductive material and are preferably formed of a metal such as aluminum, aluminum alloys, tungsten, or copper.

In one embodiment of the invention, when a sufficient bias (e.g., a hundred mV or more) is applied across the anode and the cathode, metallic ions (e.g., Ag⁺) move from the anode (e.g., made of silver) and/or from in the liquid (e.g., ions originally provided in the liquid) toward the nucleation sites on the particles. Metallic ions at the nucleation sites are reduced to form a metal structure, which grows and extends from the nucleation sites out onto the surface of the substrate. The amount of electrodeposited material is determined by factors such as the applied voltage, the identity of the metal, the identity of the liquid, the ion current magnitude and the time during which the current is allowed to flow. Electrodeposits can have significant growth parallel to as well as normal to the substrate surface. The applied bias can be, for example, in the range of 200 mV to 20 V, but the person of skill in the art will appreciate that other bias strengths can be used, and will select an appropriate bias strength to provide the desired growth of a given metal and electrode configuration.

As in any plating operation, the ions nearest the electron-supplying cathode will generally be reduced first. However, in real-world devices in which the nanoscale roughness of the electrodes is significant and the fields are relatively high, statistical non-uniformities in the ion concentration and in the electrode topography will tend to promote localized deposition or nucleation rather than blanket plating. Even if multiple nuclei are formed, the ones with the highest field and best ion supply will be favored for subsequent growth, extending out from the particles as individual elongated metallic features. The deposition interface continually moves toward the anode, increasing the field and thereby speeding the overall growth rate of the electrodeposit.

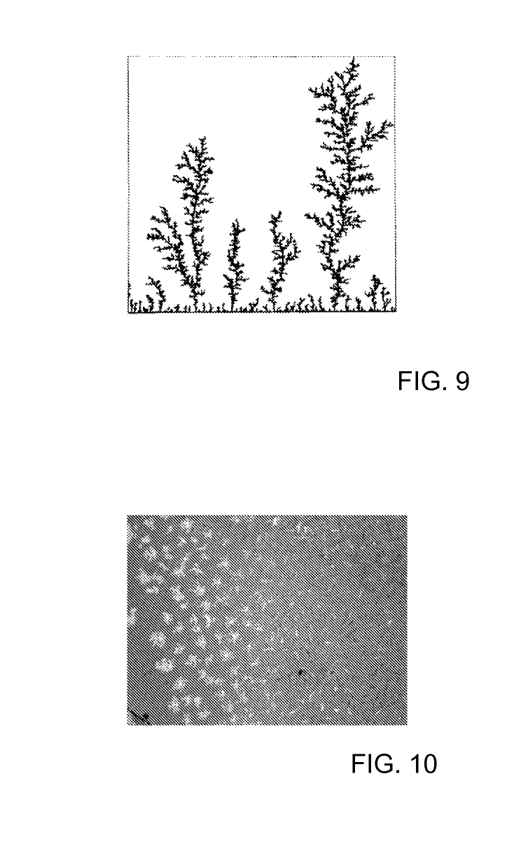

While not intending to be limited by theory, the inventor surmises that the addition of new atoms to the growing electrodeposit occurs through a diffusion-limited aggregation mechanism. In this growth process, an immobile “seed” is fixed on a plane in which particles are randomly moving. Particles that move close enough to the seed in order to be attracted to it attach and form the aggregate. When the aggregate consists of multiple particles, growth proceeds outwards and with greater speed as the new deposits extend to capture more moving particles. Thus, the branches of the core clusters grow faster than the interior regions. The precise morphology depends on parameters such as the potential difference and the concentration of metal ions in the liquid. For high ion concentrations and high fields as are common in the devices described herein, the moving ions have a strong directional component, and dendrite formation occurs. The dendrites have a branched structure, but tend to grow along a preferred axis largely defined by the applied electric field. For example, FIG. 9 shows dendritic metal structures grown between parallel electrodes (i.e., an anode at the top of the figure and a cathode at the bottom of the figure) using methods described in International Patent Application Publication no. 2010/077622. Accordingly, placement of the electrodes can be used to provide a desired directionality of electrode growth when used to deposit on metal particles as described herein.

Metal structure growth causes a mass transfer of metal from the liquid to the growing metal structure. When the liquid is not replenished with metal (e.g., by an anode), growth can significantly deplete the liquid of metal. Accordingly, in such situations, it can be desirable to use a larger volume of liquid (e.g., using a vessel of liquid, as described above).

The liquid can be selected by the person of skill in the art, such that it dissolves the metal to be used in the growing metal structure. In certain embodiments, the liquid is somewhat conductive. Aqueous media can be used as the liquid. For example, the liquid can be water, or an aqueous solution of electrolyte. As described above, in certain embodiments, the liquid provides metal ions from which the metal structure is formed (for example, as a silver salt such as AgC1 or a copper salt such as CuSO₄). It may be desirable to include a surfactant to aid in wetting of the necessary surfaces.

After deposition, the liquid can be removed from the surface of the substrate. For example, when the liquid is provided as a thin layer, it can be removed by methods such as blowing, spinning, gravity or suction. When the liquid is provided in a vessel, the workpiece can simply be removed from the vessel. In any case, it may be desirable to rinse the workpiece after deposition, especially when the liquid is of high ionic strength. Additionally, when the anode and/or the cathode can be removed after deposition.

In certain embodiments of the invention, the bias voltage is in the range of 200 mV to 20 V, depending on the particular materials and configurations used.

The methods of the present invention can be performed at room temperature. Accordingly, the resulting materials can be formed with minimal residual/intrinsic stress, making them particularly well-suited for thin substrate applications (e.g., thin crystalline solar cells) in which the stress inherent in fabricating other conductor systems causes warping.

The electrodeposition process can cause growth in the direction normal to the surface, creating metal structures of substantial thickness (e.g., in the range of 50 nm-500 nm, or even 100 nm-500 nm).

Growth rates will depend on the ion flux per unit area. Lateral growth rates can be, for example, in the range of 1-50 μm/s.

Another advantage according to certain embodiments of the invention is that the electrodeposited metal structures can be tuned or repaired (e.g., in the field) at a later time. The person need only provide an anode, a cathode, and a liquid to the surface, and apply the necessary bias across the electrodes. Electrodeposition can continue until the local bias drops below the electrodeposition threshold. High resistance regions can exist, for example, in damaged sections of the dendritic metal structure, in which case such growth can be used to repair the structure. Damage to the dendritic metal structures caused by, for example, thinning at topographical features, stress during packaging, temperature or mechanical shock in the field, can be repaired thereby.

Moreover, the growth or dissolution of the metal structures can be used to tune the plasmonic response. For example, in one embodiment, the plasmonic response is monitored as the bias is applied; the process can be stopped when the desired response is achieved. The bias can be reversed to remove metal from the metal structures, thereby shifting the response toward that of the particles alone.

The substrate can take many forms, as described in more detail with respect to devices, above. Notably, the plasmoic structures can be disposed on a wide variety of devices. The surface of the substrate can be formed, for example, from germanium oxide, silicon oxide, nitride, or oxynitride, silicon, compound semiconductors, or polymeric materials. In certain embodiments, the surface of the substrate is substantially non-conductive (e.g., an insulator or a semiconductor, for example with a conductivity no greater than 0.001 Ohm-cm.). Desirably, substantially no solid electrolyte (e.g., as described in U.S. Pat. no. 6,635,914 or International Patent Application Publication 2010/077622) is in contact with the metal structure.

In certain embodiments of the invention, the plasmonic structure is disposed on an insulating layer. An insulating layer can be suitable for use with a conductive device (e.g., photovoltaic cell). When the device is not substantially less conductive than the liquid used to deposit the metal structure, the bias applied across the anode and cathode for electrodeposition can cause current flow through the device instead of through the liquid, thereby greatly reducing the speed of electrodeposition.

In one example, a 16 nm thick Ag film on SiO₂ was annealed at 200° C. for 50 minutes to form silver particles. While the film exhibited no resonance before annealing, after annealing a strong “bare island” resonance at a wavelength of 450 nm was observed. The optical characteristics were further changed by growth of dendritic metal structures, substantially as described above. The dendrite growth was substantial, as evidenced by the reduction of the measured series resistance to a few tens of Ohms. A hybrid transmission spectrum, between the transmission spectrum of the film and that of the particles, was observed. A slight red-shift of the resonance region was also observed. FIG. 10 is an optical micrograph, showing the clusters of dendritic silver structures extending from the silver particles.

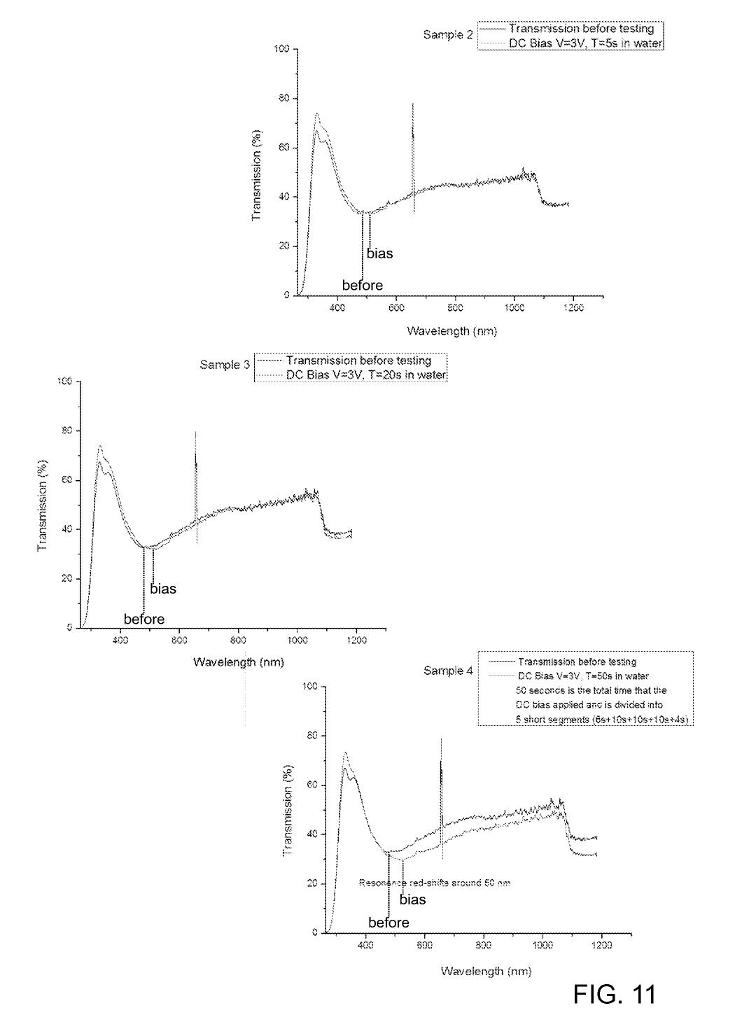

A series of experiments were performed as follows: Glass slides were cleaned, then 10 nm of Ag was evaporated thereon, followed by annealing at 200° C. for 50 min. The transmission was measured as a control. Then a few drops of water were disposed on the slides (i.e., to cover), and a DC bias was applied. In Sample 2, the DC bias was 3 V for 5 sec. In Sample 3, the DC bias was 3 V for 20 sec. In Sample 4, the DC bias was 3 V, divided into 5 short segments (6 sec; 10 sec; 10 sec; 10 sec; 4 sec). In this example, the anode was a ring formed on the substrate, and a cathode suspended in the middle of the ring area. As shown in FIG. 11, all three samples exhibited a red shift of the resonance, with Sample 4 exhibiting about a 50 nm shift.

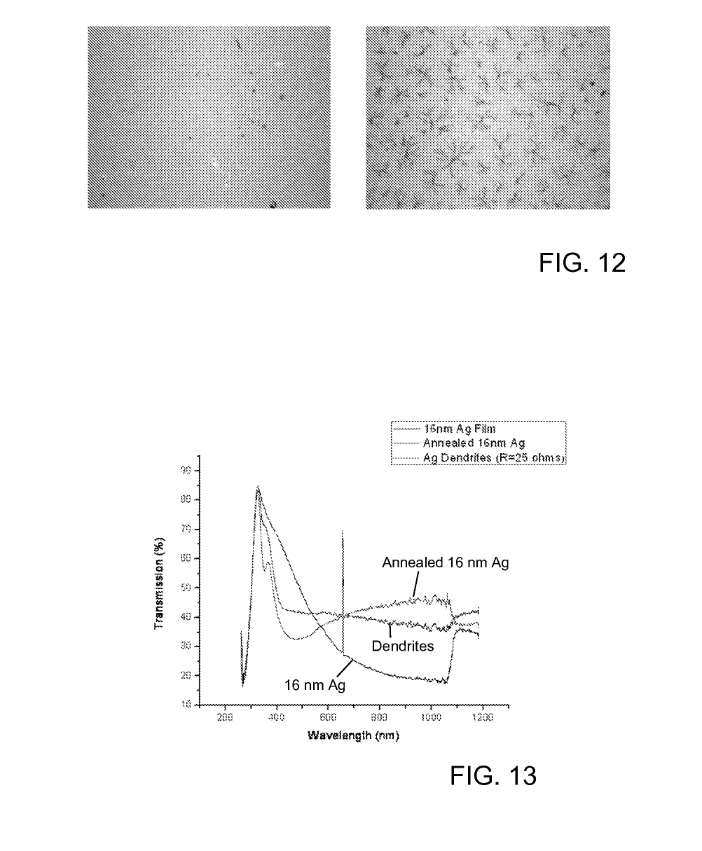

In another experiment, a continuous 16 nm thick Ag film was evaporated onto a SiO₂ layer, then annealed to form particles. Dendritic silver structures were grown in water with a bias of 1.5 volts, providing a sheet resistance of 25 Ohms. FIG. 12 provides a micrograph of the particles as annealed (left picture), and the particles with dendritic silver structures extending therefrom (right picture). The transmission spectra of the film as deposited, as annealed, and with the dendrites are provided in FIG. 13. Plasmonic resonance is visible in the annealed film, but appears to red-shift slightly with dendrite growth.

Unless clearly excluded by the context, all embodiments disclosed for one aspect of the invention can be combined with embodiments disclosed for other aspects of the invention, in any suitable combination.

It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

What is claimed is:

1. A plasmonic structure comprising:
a substrate;
a plurality of metal particles disposed on the substrate; and
one or more metal structures electrically coupled to and disposed on a surface of each of the plurality of metal particles, the metal having a structure different from the structure of the metal particles.

2. The plasmonic structure according to claim 1, wherein the one or more metal structures are formed by electrodeposition.

3. The plasmonic structure according to claim 1, wherein the plurality of metal particles has an average diameter in the range of about 5 nm to about 2 μm

4. The plasmonic structure according to claim 1, wherein the plurality of metal particles has an average nearest neighbor distance in the range of about 5 nm to about 2 μm

5. The plasmonic structure according to claim 1, wherein the metal particles are formed from silver, copper, or gold.

6. The plasmonic structure according to claim 1, wherein the metal particles are formed from aluminum.

7. The plasmonic structure according to claim 1, wherein the metal particles are substantially hemispherical in shape.

8. The plasmonic structure according to claim 1, wherein the metal structures electrically interconnect the plurality of metal particles.

9. The plasmonic structure according to claim 1, wherein the metal structure is formed from silver or copper.

10. The plasmonic structure according to claim 1, wherein the metal structure is a dendritic metal structure.

11. The plasmonic structure according to claim 10, wherein the at least one dendritic metal structure is no more than about 200 nm in average thickness.

12. The plasmonic structure according to claim 10, wherein the at least one dendritic metal structure has an average individual segment width of no more than about 1 μm.

13. The plasmonic structure according to claim 1, wherein the metal particles are at least partially embedded in a dielectric or semiconductor material.

14. The plasmonic structure according to claim 1, wherein substantially no solid electrolyte is in contact with the metal structure and the metal particles.

15. The plasmonic structure according to claim 1, wherein the substrate comprises a photovoltaic cell.

16. The plasmonic structure according to claim 15, wherein the photovoltaic cell is a single crystal Si photovoltaic cell, an amorphous Si photovoltaic cell, a silicon-on-insulator photovoltaic cell, a III-V semiconductor photovoltaic cell, a II-VI semiconductor photovoltaic cell, a CuInSe₂ photovoltaic cell, or a quantum well photovoltaic cell.

17. The plasmonic structure according to claim 15, wherein the light-absorbing photovoltaic layer of the photovoltaic cell is less than about 50 μm in thickness.

18. The plasmonic structure according to claim 1, wherein the substrate comprises an optical sensor.

19. A method for making a plasmonic structure, the method comprising:
providing a substrate having disposed thereon a plurality of metal particles;
providing an anode and a cathode and disposing a liquid on the surface of the substrate, such that the liquid is in electrical contact with the anode, the cathode and the plurality of metal particles; and
applying a bias voltage across the metal particles and the anode sufficient to grow one or more metal structures electrically coupled to and disposed on each of the plurality of metal particles.

20. The method according to claim 19, wherein the anode is disposed on the top surface of the substrate.

21. The method according to claim 19, wherein the liquid is an aqueous liquid.

22. The method according to claim 19, wherein the liquid is an aqueous solution of electrolyte.

23. The method according to claim 19, further comprising removing the liquid from the top surface of the substrate after applying the bias voltage to grow the metal structure.

24. The method according to claim 19, wherein the metal structure is a dendritic metal structure.

25. The method according to claim 19, wherein the metal particles are formed by depositing metal on the substrate, then heating the metal to cause surface tension induced agglomeration.
